(19) United States
(12) Patent Application Publication
(10) Pub. No.: US 2013/0205910 A1
(43) Pub. Date: Aug. 15, 2013

(54) NOVEL EMBEDDED 3D STRESS AND TEMPERATURE SENSOR UTILIZING SILICON DOPING MANIPULATION

(71) Applicants: Hossam Mohamed Hamdy Gharib, Edmonton (CA); Walied Ahmed Mohamed Moussa, Edmonton (CA)

(72) Inventors: Hossam Mohamed Hamdy Gharib, Edmonton (CA); Walied Ahmed Mohamed Moussa, Edmonton (CA)

(73) Assignee: The Governors of the University of Alberta, Edmonton, AB (CA)

(21) Appl. No.: 13/880,354

(22) PCT Filed: Nov. 25, 2011
(86) PCT No.: PCT/CA2011/001282

§ 371 Date: Apr. 18, 2013

Related U.S. Application Data
(60) Provisional application No. 61/417,110, filed on Nov. 24, 2010.

(51) Int. Cl. G01L 1/22; H01L 29/84

(52) U.S. Cl. CPC G01L 1/2293; H01L 29/84
USPC 73/777; 257/417

(57) ABSTRACT

A new approach for building a stress-sensing rosette capable of extracting the six stress components and the temperature is provided, and its feasibility is verified both analytically and experimentally. The approach can include varying the doping concentration of the sensing elements and utilizing the unique behaviour of the shear piezoresistive coefficient (π₄₄) in n-Si.

### CROSS REFERENCE TO RELATED APPLICATIONS

This application claims priority of U.S. provisional patent application Ser. No. 61/417,110 filed Nov. 24, 2010, and hereby incorporates the same provisional application by reference herein in its entirety.

### TECHNICAL FIELD

The present disclosure is related to the field of piezoresistive stress sensors, in particular, piezoresistive stress sensors that are capable of extracting all six stress components with temperature compensation.

### BACKGROUND

The measurement of stresses and strains is essential for the inspection, monitoring and testing of structural integrity. A commonly used technique for stress and strain monitoring is the use of metallic strain gauges. These gauges utilize the strain-electrical resistance coupling to evaluate the in-plane strains when they are surface mounted to a structure, which is useful in structural health monitoring of machinery, bridges and bio-implants. However, if an evaluation of the out-of-plane normal and shear stress/strain components is required, metallic strain gauges offer limited advantage.

An alternative technique to overcome this limitation would be to use the silicon piezoresistive stress/strain gauges, which can offer higher sensitivity compared to metallic strain gauges, ability to measure out-of-plane stress/strain components and provide in situ real-time non-destructive stress measurements. The majority of the developed piezoresistive stress/strain sensors use elements that sense in-plane stress and/or strain components for applications in pressure sensors [1] microcantilevers [2], or strain gauges [3]. However, fewer efforts are spent towards the utilization of the unique properties of crystalline silicon to develop a piezoresistive three-dimensional (3D) stress sensor that measures the six stress components. These types of 3D stress sensors can be valuable in applications where the sensor and the monitored structure are of the same material, such as in cases where an electronic chip is used to measure the stresses due to packaging and thermal loads [4, 5]. Also, a 3D stress sensor can be used in applications where the sensor is embedded within a host material to monitor the stresses and strains at the sensor/host material interface. In the latter case, a coupling scheme can be used to link the stresses and strains in the sensor to those in the host material [6, 7].

The piezoresistive effect in silicon was observed through experimental testing by Smith [8] and Paul et al. [9] in the 1950s. Since then, a lot of research work has been conducted to study the piezoresistive effect and its relation to other parameters like electrical resistivity, electrical mobility, impurity concentration and temperature. The change in resistance of a piezoresistive filament can be related to the applied stress and/or temperature through the piezoresistive coefficients and temperature coefficient of resistance (TCR), respectively. Piezoresistive coefficients were studied experimentally by Tufte et al, [10, 11], Kerr et al. [12], Morin et al. [13], and Richter et al. [14]. Analytical modeling of the piezoresistive coefficients and their relation to temperature and impurity concentration can be attributed to Kanda at a/, who provided graphical representation of the piezoresistive coefficients with crystallographic orientation [15, 16]. Also, they presented analytical and experimental studies for the first and second order piezoresistive coefficients in both p-type and n-type silicon [17-21]. Other theoretical modeling of the piezoresistive effect was introduced by Kozlovsky et al. [22], Toriyama et al. [23] and Richter et al. [24]. Temperature coefficient of resistance in silicon was studied by Bullis et al. [25] and Norton et al. [26]. A study on the effect of doping concentration on the first and second order temperature coefficient of resistance was conducted by Boukabache et al. using the models for majority carriers mobility in silicon [27].

The first piezoresistive stress-sensing rosette capable of extracting four of the six stress components was designed by Miura et al. [28]. This sensing rosette is made up of two p-type and two n-type sensing elements on (001) silicon wafer plane and extracts the three in-plane stress components and out-of-plane normal stress component. The first comprehensive presentation of the theory of piezoresistive stress-sensing rosettes was given by Bittle et al. [29] and later re-constructed by Suhling et al. to include the effect of temperature on the resistance change equations and study the application of stress-sensing rosettes to electronic packaging [5]. The aforementioned two studies introduced the first piezoresistive dual-polarity stress-sensing rosette fabricated on (111) silicon using both n- and p-type sensing elements that can extract the six stress components. The extracted stresses were partially temperature-compensated, where only four stresses are temperature-compensated, namely the three shear stresses and the difference of the in-plane normal stresses. Their inability to extract all stresses with temperature-compensation is due to the limitation in the number of independent equations that hinders the ability to eliminate the effect of temperature on the change in electrical resistance of the sensing elements. Other studies for the development of 3D piezoresistive stress sensors for electronic packaging applications include the works of Schwizer et al. [4], Lwo et al. [30], and Mian et al. [31].

To the inventors' knowledge, for all developed 3D stress sensors publicly available, none are capable of extracting all six stress components with temperature compensation. It is, therefore, desirable to provide 3D stress sensors that overcome the shortcomings of the prior art.

### SUMMARY

A novel approach is provided to building an embedded micro dual sensor that can monitor stresses in 3 dimensions (“3D”) and temperature. The approach can use only n-type or a combination of n- and p-type silicon doped piezoresistive sensing elements to extract the six stress components and temperature.

In some embodiments, the approach can be based on generating a new set of independent linear equations through the variation in doping concentration of the sensing elements to develop a fully temperature-compensated stress-sensing rosette.

In some embodiments, the rosette can comprise an all n-type (single-polarity) 3D stress-sensing rosette instead of the combined p- and n-type (dual-polarity). In some embodiments, a single-polarity approach can reduce the complexity associated with the microfabrication of the dual-polarity rosette and can enable further miniaturization of the size of the rosette footprint.

Incorporated by reference into this application is a paper written by the within inventors entitled, “On the Feasibility of a New Approach for Development a Piezoresistive 3D Stress-sensing Rosette”, submitted for publication in IEEE Sensors Journal, to be published Dec. 1, 2010.

Broadly stated, in some embodiments, stress sensor is provided, comprising: a semiconductor substrate; a plurality of piezoresistive resistors disposed on the substrate, the resistors spaced-apart on the substrate in a rosette formation, the resistors operatively connected together to form a circuit network wherein the resistance of each resistor can be measured; and the plurality of piezoresistive resistors comprising a first group of resistors, a second group of resistors and a third group of resistors wherein the three groups are configured to measure six temperature-compensated stress components in the substrate when the sensor is under stress or strain.

Broadly stated, in some embodiments, a strain gauge is provided comprising a sensor, the sensor comprising: a semiconductor substrate; a plurality of piezoresistive resistors disposed on the substrate, the resistors spaced-apart on the substrate in a rosette formation, the resistors operatively connected together to form a circuit network wherein the resistance of each resistor can be measured; and the plurality of piezoresistive resistors comprising a first group of resistors, a second group of resistors and a third group of resistors wherein the three groups are configured to measure six temperature-compensated stress components in the substrate when the sensor is under stress or strain.

Broadly stated, in some embodiments, a method is provided for measuring the strain on an electronic chip comprising a semiconductor substrate, the method comprising the steps of: fabricating the electronic chip with a plurality of piezoresistive resistors disposed on the substrate, the resistors spaced-apart on the substrate in a rosette formation, the resistors operatively connected together to form a circuit network wherein the resistance of each resistor can be measured, the plurality of piezoresistive resistors comprising a first group of resistors, a second group of resistors and a third group of resistors wherein the three groups are configured to measure six temperature-compensated stress components in the substrate when the sensor is under stress or strain; subjecting the electronic chip to a mechanical or thermal load; measuring the resistance of the resistors; and determining the six temperature compensated stress components of the substrate from the resistance measurements.

Broadly stated, in some embodiments, a method is provided for measuring strain or stress on a structural member, the method comprising the steps of: placing a strain gauge on or within the structural member, the strain gauge comprising a sensor, the sensor further comprising: a semiconductor substrate, a plurality of piezoresistive resistors disposed on the substrate, the resistors spaced-apart on the substrate in a rosette formation, the resistors operatively connected together to form a circuit network wherein the resistance of each resistor can be measured, and the plurality of piezoresistive resistors comprising a first group of resistors, a second group of resistors and a third group of resistors wherein the three groups are configured to measure six temperature-compensated stress components in the substrate when the sensor is under stress or strain; subjecting the structural member to a mechanical or thermal load; measuring the resistance of the resistors; and determining the six temperature compensated stress components of the substrate from the resistance measurements.

### BRIEF DESCRIPTION OF THE DRAWINGS

FIG. 1 is a three-dimensional graph depicting a filamentary silicon conductor.

FIG. 2 is a two-dimensional graph depicting a silicon wafer with filament orientation.

FIG. 3 is a two-dimensional graph depicting a ten-element piezoresistive sensor.

FIG. 4 is a contour plot depicting the effect of doping concentration of groups a and b on |D₁| for an npp rosette.

FIG. 5 is a contour plot depicting the effect of doping concentration of groups a and b on |D₂| for an npp rosette.

FIG. 6 is a contour plot depicting the effect of doping concentration of groups a and b on |D₁| for an nnn rosette.

FIG. 7 is a contour plot depicting the effect of doping concentration of groups a and b on |₂| for an nnn rosette.

FIG. 8 is a two-dimensional graph depicting the effect of doping on B in p-Si.

FIG. 9 is a two-dimensional graph depicting the effect of doping on B in n-Si.

FIG. 10 is a two-dimensional graph depicting the effect of doping on TCR in n-Si and p-Si.

FIG. 11 is a microphotograph of a fabricated nnn rosette.

FIG. 12 is a perspective view depicting a four-point bending loading fixture.

FIG. 13 is a photograph depicting the probing of piezoresistors under uniaxial loading with a physical implementation of the fixture of FIG. 12.

FIG. 14 is a two-dimensional graph depicting typical stress sensitivity from four-point bending measurements for R₀.

FIG. 15 is a two-dimensional graph depicting typical stress sensitivity from four-point bending measurements for R₉₀.

FIG. 16 is a two-dimensional graph depicting typical temperature sensitivity measurements.

### DETAILED DESCRIPTION OF EMBODIMENTS

### Theoretical Background

A piezoresistive sensing rosette developed over crystalline silicon depends on the orientation of the sensing elements with respect to the crystallographic coordinates of the silicon crystal structure. An arbitrary oriented piezoresistive filament with respect to the silicon crystallographic axes is shown in FIG. 1. The unprimed coordinates represent the principal crystallographic directions of silicon, i.e. X₁=[100] X₂=[010], and X₃=[001], while the primed axes represent an arbitrary rotated coordinate system with respect to the principal crystallographic directions.

The change in electrical resistance of a piezoresistive filament due to an applied stress and temperature along the primed axes is given by [5]:

$$\begin{matrix}\frac{Δ R}{R} = \frac{R ( σ , T ) - R ( 0 , 0 )}{R ( 0 , 0 )} \\ = ( {π}_{1 β}^{′} {σ}_{β}^{′} ) {l}^{′2} + ( {π}_{2 β}^{′} {σ}_{β}^{′} ) {m}^{′2} + ( {π}_{3 β}^{′} {σ}_{β}^{′} ) {n}^{′2} + \\ 2 ( {π}_{4 β}^{′} {σ}_{β}^{′} ) {l}^{′} {n}^{′} + 2 ( {π}_{5 β}^{′} {σ}_{β}^{′} ) {m}^{′} {n}^{′} + 2 ( {π}_{6 β}^{′} {σ}_{β}^{′} ) {l}^{′} {m}^{′} + \\ [ {α}_{1} T + {α}_{2} {T}^{2} + … ]\end{matrix} \qquad ( 1 )$$

### Where,

R(σ, T)=resistor value with applied stress and temperature change
R(0, 0)=reference resistor value without applied stress and temperature change
π′_{γ,β}=off-axis temperature dependent piezoresistive coefficients with γ, β=1, 2, . . . 6
σ′_{β}=stress in the primed coordinate system, β=1, 2, . . . , 6
α₁, α₂, . . . =first and higher order temperature coefficients of resistance (TCR)
T=T_{c}−T_{ref}=difference between the current measurement temperature (T_{c}) and reference temperature (T_{ref})
l′, m′, n′=direction cosines of the filament orientation with respect to the x′₁, x′₂, and x′₃ axes

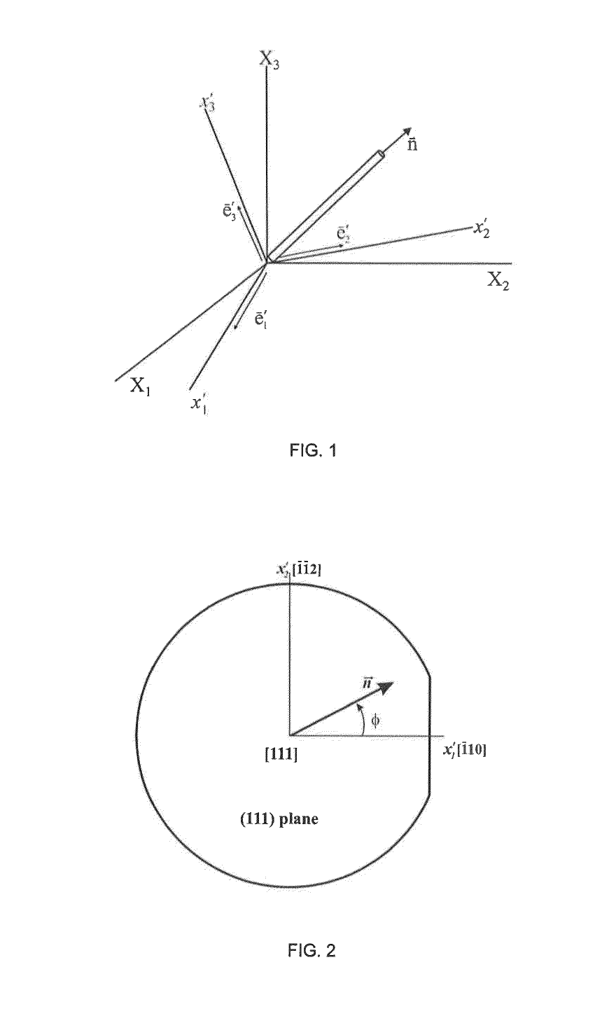

The orientation defined by the primed axes for a set of piezoresistive filaments forming a rosette determines the number of stress components that can be extracted. For example, a rosette oriented over the (001) plane can be used to measure the in-plane stress components and the out-of-plane normal component. On the other hand, a rosette oriented over the (111) plane can extract the six stress components. Moreover, a (001) rosette can extract two temperature-compensated stress components, while the (111) rosette can extract four temperature-compensated stress components by eliminating the component (αT) in equation (1) [32]. Therefore, to develop a 3D stress sensing rosette over the (111) wafer plane, equation (1) is reformulated into:

$$\frac{Δ R}{R} = ( {B}_{1} {cos}^{2} φ + {B}_{2} {sin}^{2} φ ) {σ}_{11}^{′} + ( {B}_{2} {cos}^{2} φ + {B}_{1} {sin}^{2} φ ) {σ}_{22}^{′} + {B}_{3} {σ}_{33}^{′} + 2 \sqrt{2} ( {B}_{2} - {B}_{3} ) ( {cos}^{2} φ - {sin}^{2} φ ) {σ}_{23}^{′} + 2 \sqrt{2} ( {B}_{2} - {B}_{3} ) sin 2 φ {σ}_{13}^{′} + ( {B}_{1} - {B}_{2} ) sin 2 φ {σ}_{12}^{′} + α T \qquad ( 2 )$$

In which only the first order temperature coefficient of resistance (α) is considered, φ is the angle defining the orientation of a piezoresistive filament over the (111) plane as shown in FIG. 2 and Bᵢ (i=1, 2, 3) is a function of the crystallographic piezoresistive coefficients as follows:

$${B}_{1} = \frac{{π}_{11} + {π}_{12} + {π}_{44}}{2} , {B}_{2} = \frac{{π}_{11} + 5 {π}_{12} - {π}_{44}}{6} , \\ and \\ {B}_{3} = \frac{{π}_{11} + 2 {π}_{12} - {π}_{44}}{3} \qquad ( 3 )$$

### Sensing Rosette Theory (Current Approach)

### Basic Concept

The 3D stress sensing rosette presented by Suhling et al. is made up of eight sensing elements; four n-type and four p-type [5]. Suhling et al. reported in this study that a (111) sensing rosette fabricated from identically doped sensing elements (single-polarity) can only extract three stress components. On the other hand, a (111) dual-polarity rosette can extract the six stress components because it provides enough linearly independent responses from the sensing elements.

In fact, the dual-polarity rosette provides two sets of independent piezoresistive coefficients (π) and temperature coefficients of resistance (α), which generate linearly independent equations to extract the six stresses with partial temperature-compensation. Therefore, if it is possible to have two groups of sensing elements (not necessarily dual-polarity) with independent π and α, the partially temperature-compensated six stress components can be extracted. Moreover, if a third group with different π and α is added, fully temperature-compensated stress components can be extracted.

Solution for Stresses

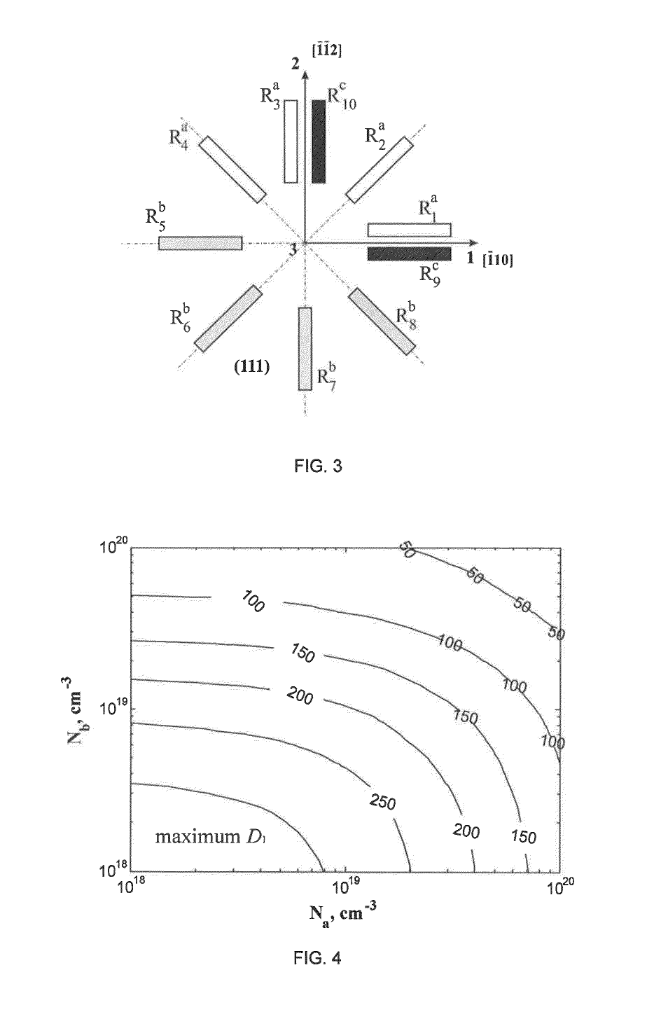

In some embodiments, a rosette can be made up of ten sensing elements developed over the (111) wafer plane as shown in FIG. 3 and can be divided into three groups (a, b, and c), where each group has linearly independent g and a. Eight of these elements, forming groups a and b, can be used to solve for the four temperature-compensated stresses similar to the dual-polarity rosette of Suhling et al. [5]. The extra two sensing elements forming the third group c can be used to solve for the remaining temperature-compensated stress components. Application of equation (2) to the rosette gives ten equations describing the resistance change with the applied stress and temperature:

$$( \frac{Δ {R}_{1}}{{R}_{1}} ) = {B}_{1}^{a} {σ}_{11}^{′} + {B}_{2}^{a} {σ}_{22}^{′} + {b}_{3}^{a} {σ}_{33}^{′} + 2 \sqrt{2} ( {B}_{2}^{a} - {B}_{3}^{a} ) {σ}_{23}^{′} + {α}^{a} T \\ ( \frac{Δ {R}_{2}}{{R}_{2}} ) = ( \frac{{B}_{1}^{a} + {B}_{2}^{a}}{2} ) {σ}_{11}^{′} + ( \frac{{B}_{1}^{a} + {B}_{2}^{a}}{2} ) {σ}_{22}^{′} + {B}_{3}^{a} {σ}_{33}^{′} + 2 \sqrt{2} ( {B}_{2}^{a} - {B}_{3}^{a} ) {σ}_{13}^{′} + ( {B}_{1}^{a} - {B}_{2}^{a} ) {σ}_{12}^{′} + {α}^{a} T \\ ( \frac{Δ {R}_{3}}{{R}_{3}} ) = {B}_{2}^{a} {σ}_{11}^{′} + {B}_{1}^{a} {σ}_{22}^{′} + {B}_{3}^{a} {σ}_{33}^{′} - 2 \sqrt{2} ( {B}_{2}^{a} - {B}_{3}^{a} ) {σ}_{23}^{′} + {α}^{a} T \\ ( \frac{Δ {R}_{4}}{{R}_{4}} ) = ( \frac{{B}_{1}^{a} + {B}_{2}^{a}}{2} ) {σ}_{11}^{′} + ( \frac{{B}_{1}^{a} + {B}_{2}^{a}}{2} ) {σ}_{22}^{′} + {B}_{3}^{a} {σ}_{33}^{′} - 2 \sqrt{2} ( {B}_{2}^{a} - {B}_{3}^{a} ) {σ}_{13}^{′} - ( {B}_{1}^{a} - {B}_{2}^{a} ) {σ}_{12}^{′} + {α}^{a} T \\ ( \frac{Δ {R}_{5}}{{R}_{5}} ) = {B}_{1}^{b} {σ}_{11}^{′} + {B}_{2}^{b} {σ}_{22}^{′} + {B}_{3}^{b} {σ}_{33}^{′} + 2 \sqrt{2} ( {B}_{2}^{b} - {B}_{3}^{b} ) {σ}_{23}^{′} + {α}^{b} T \\ ( \frac{Δ {R}_{6}}{{R}_{6}} ) = ( \frac{{B}_{1}^{b} + {B}_{2}^{b}}{2} ) {σ}_{11}^{′} + ( \frac{{B}_{1}^{b} + {B}_{2}^{b}}{2} ) {σ}_{22}^{′} + {B}_{3}^{b} {σ}_{33}^{′} + 2 \sqrt{2} ( {B}_{2}^{b} - {B}_{3}^{b} ) {σ}_{13}^{′} + ( {B}_{1}^{b} - {B}_{2}^{b} ) {σ}_{12}^{′} + {α}^{b} T \\ ( \frac{Δ {R}_{7}}{{R}_{7}} ) = {B}_{2}^{b} {σ}_{11}^{′} + {B}_{1}^{b} {σ}_{22}^{′} + {B}_{3}^{b} {σ}_{33}^{′} - 2 \sqrt{2} ( {B}_{2}^{b} - {B}_{3}^{b} ) {σ}_{23}^{′} + {α}^{b} T \\ ( \frac{Δ {R}_{8}}{{R}_{8}} ) = ( \frac{{B}_{1}^{b} + {B}_{2}^{b}}{2} ) {σ}_{11}^{′} + ( \frac{{B}_{1}^{b} + {B}_{2}^{b}}{2} ) {σ}_{22}^{′} + {B}_{3}^{b} {σ}_{33}^{′} - 2 \sqrt{2} ( {B}_{2}^{b} - {B}_{3}^{b} ) {σ}_{13}^{′} - ( {B}_{1}^{b} - {B}_{2}^{b} ) {σ}_{12}^{′} + {α}^{b} T \\ ( \frac{Δ {R}_{9}}{{R}_{9}} ) = {B}_{1}^{c} {σ}_{11}^{′} + {B}_{2}^{c} {σ}_{22}^{′} + {B}_{3}^{c} {σ}_{33}^{′} + 2 \sqrt{2} ( {B}_{2}^{c} - {B}_{3}^{c} ) {σ}_{23}^{′} + {α}^{c} T \\ ( \frac{Δ {R}_{10}}{{R}_{10}} ) = {B}_{2}^{c} {σ}_{11}^{′} + {B}_{1}^{c} {σ}_{22}^{′} + {B}_{3}^{c} {σ}_{33}^{′} - 2 \sqrt{2} ( {B}_{2}^{c} - {B}_{3}^{c} ) {σ}_{23}^{′} + {α}^{c} T \qquad ( 4 )$$

Superscripts a, b, and c can indicate the different groups of elements. The evaluation of the stresses and temperature can be carried out by the subtraction and addition of equations (4) to give:

Equations for the evaluation of (σ′₁₁−σ′₂₂) and σ′₂₃

$$[ \begin{matrix}\frac{Δ {R}_{1}}{{R}_{1}} - \frac{Δ {R}_{3}}{{R}_{3}} \\ \frac{Δ {R}_{5}}{{R}_{5}} - \frac{Δ {R}_{7}}{{R}_{7}}\end{matrix} ] = [ \begin{matrix}( {B}_{1}^{a} - {B}_{2}^{a} ) & 4 \sqrt{2} ( {B}_{2}^{a} - {B}_{3}^{a} ) \\ ( {B}_{1}^{b} - {B}_{2}^{b} ) & 4 \sqrt{2} ( {B}_{2}^{b} - {B}_{3}^{b} )\end{matrix} ] [ \begin{matrix}( {σ}_{11}^{′} - {σ}_{22}^{′} ) \\ {σ}_{23}^{′}\end{matrix} ] \qquad ( 5 )$$

Equations for the evaluation of σ′₁₃ and σ′₁₂

$$[ \begin{matrix}\frac{Δ {R}_{2}}{{R}_{2}} - \frac{Δ {R}_{4}}{{R}_{4}} \\ \frac{Δ {R}_{6}}{{R}_{6}} - \frac{Δ {R}_{8}}{{R}_{8}}\end{matrix} ] = [ \begin{matrix}4 \sqrt{2} ( {B}_{2}^{a} - {B}_{3}^{a} ) & 2 ( {B}_{1}^{a} - {B}_{2}^{a} ) \\ 4 \sqrt{2} ( {B}_{2}^{b} - {B}_{3}^{b} ) & 2 ( {B}_{1}^{b} - {B}_{2}^{b} )\end{matrix} ] [ \begin{matrix}{σ}_{13}^{′} \\ {σ}_{12}^{′}\end{matrix} ] \qquad ( 6 )$$

Equations for the evaluation of (σ′₁₁+σ′₂₂), σ′₃₃, and T

$$[ \begin{matrix}\frac{Δ {R}_{1}}{{R}_{1}} + \frac{Δ {R}_{3}}{{R}_{3}} \\ \frac{Δ {R}_{5}}{{R}_{5}} + \frac{Δ {R}_{7}}{{R}_{7}} \\ \frac{Δ {R}_{9}}{{R}_{9}} + \frac{Δ {R}_{10}}{{R}_{10}}\end{matrix} ] = [ \begin{matrix}( {B}_{1}^{a} + {B}_{2}^{a} ) & 2 {B}_{3}^{a} & 2 {α}^{a} \\ ( {B}_{1}^{b} + {B}_{2}^{b} ) & 2 {B}_{3}^{b} & 2 {α}^{b} \\ ( {B}_{1}^{c} + {B}_{2}^{c} ) & 2 {B}_{3}^{c} & 2 {α}^{c}\end{matrix} ] [ \begin{matrix}( {σ}_{11}^{′} + {σ}_{22}^{′} ) \\ {σ}_{33}^{′} \\ T\end{matrix} ] \qquad ( 7 )$$

The expressions in (5)-(7) can be inverted to solve for the stresses and temperature in terms of the measured resistance changes as shown in (8)-(10), where D₁ can describe the determinants of the coefficients in (5) and (6), and D₂ can describe the determinant of the coefficients in (7).

Dual- and Single-Polarity Rosettes

The solution of (8) requires non-zero D₁ and D₂, which means that each of the three sets of equations (5)-(7) must be linearly independent. This is achieved in two ways; using a dual-polarity rosette or a single-polarity rosette designated as npp and nnn respectively as shown in Table 1.

TABLE 1
SELECTED DOPING TYPES OF EACH ROSETTE

| Rosette | Group a | Group b | Group c |
|---|---|---|---|
| npp | n-type | p-type (1) | p-type (2) |
| nnn | n-type (1) | n-type (2) | n-type (3) |

The npp rosette can comprise n-type group a elements, and p-type groups b and c elements but with a different doping concentration designated as (1) and (2) in Table This selection of sensing elements can offer different and independent coefficients in (5)-(7), thus independency of the equations.

$$\begin{matrix}{σ}_{11}^{′} = \frac{1}{2 {D}_{2}} [ ( {B}_{3}^{c} {α}^{b} - {B}_{3}^{b} {α}^{c} ) ( \frac{Δ {R}_{1}}{{R}_{1}} + \frac{Δ {R}_{3}}{{R}_{3}} ) + ( {B}_{3}^{a} {α}^{c} - {B}_{3}^{c} {α}^{a} ) ( \frac{Δ {R}_{5}}{{R}_{5}} + \frac{Δ {R}_{7}}{{R}_{7}} ) + ( {B}_{3}^{b} {α}^{a} - {B}_{3}^{a} {α}^{b} ) ( \frac{Δ {R}_{9}}{{R}_{9}} + \frac{Δ {R}_{10}}{{R}_{10}} ) ] + \frac{1}{2 {D}_{1}} [ ( {B}_{2}^{b} - {B}_{3}^{b} ) ( \frac{Δ {R}_{1}}{{R}_{1}} - \frac{Δ {R}_{3}}{{R}_{3}} ) - ( {B}_{2}^{a} - {B}_{3}^{a} ) ( \frac{Δ {R}_{5}}{{R}_{5}} + \frac{Δ {R}_{7}}{{R}_{7}} ) ] \\ {σ}_{22}^{′} = \frac{1}{2 {D}_{2}} [ ( {B}_{3}^{c} {α}^{b} - {B}_{3}^{b} {α}^{c} ) ( \frac{Δ {R}_{1}}{{R}_{1}} + \frac{Δ {R}_{3}}{{R}_{3}} ) + ( {B}_{3}^{a} {α}^{c} - {B}_{3}^{c} {α}^{a} ) ( \frac{Δ {R}_{5}}{{R}_{5}} + \frac{Δ {R}_{7}}{{R}_{7}} ) + ( {B}_{3}^{b} {α}^{a} - {B}_{3}^{a} {α}^{b} ) ( \frac{Δ {R}_{9}}{{R}_{9}} + \frac{Δ {R}_{10}}{{R}_{10}} ) ] - \frac{1}{2 {D}_{1}} [ ( {B}_{2}^{b} - {B}_{3}^{b} ) ( \frac{Δ {R}_{1}}{{R}_{1}} - \frac{Δ {R}_{3}}{{R}_{3}} ) - ( {B}_{2}^{a} - {B}_{3}^{a} ) ( \frac{Δ {R}_{5}}{{R}_{5}} - \frac{Δ {R}_{7}}{{R}_{7}} ) ] \\ {σ}_{33}^{′} = \frac{1}{2 {D}_{2}} [ ( ( {B}_{1}^{b} + {B}_{2}^{b} ) {α}^{c} - ( {B}_{1}^{c} + {B}_{2}^{c} ) {α}^{b} ) ( \frac{Δ {R}_{1}}{{R}_{1}} + \frac{Δ {R}_{3}}{{R}_{3}} ) + ( ( {B}_{1}^{c} + {B}_{2}^{c} ) {α}^{a} - ( {B}_{1}^{a} + {B}_{2}^{a} ) {α}^{c} ) ( \frac{Δ {R}_{5}}{{R}_{5}} + \frac{Δ {R}_{7}}{{R}_{7}} ) + ( ( {B}_{1}^{a} + {B}_{2}^{a} ) {α}^{b} - ( {B}_{1}^{b} + {B}_{2}^{b} ) {α}^{a} ) ( \frac{Δ {R}_{9}}{{R}_{9}} + \frac{Δ {R}_{10}}{{R}_{10}} ) \\ {σ}_{23}^{′} = \frac{1}{{D}_{1}} [ - \frac{( {B}_{1}^{b} - {B}_{2}^{b} )}{4 \sqrt{2}} ( \frac{Δ {R}_{1}}{{R}_{1}} - \frac{Δ {R}_{3}}{{R}_{3}} ) + \frac{( {B}_{1}^{a} - {B}_{2}^{a} )}{4 \sqrt{2}} ( \frac{Δ {R}_{5}}{{R}_{5}} - \frac{Δ {R}_{7}}{{R}_{7}} ) ] \\ {σ}_{13}^{′} = \frac{1}{{D}_{1}} [ \frac{- ( {B}_{1}^{b} - {B}_{2}^{b} )}{4 \sqrt{2}} ( \frac{Δ {R}_{2}}{{R}_{2}} - \frac{Δ {R}_{4}}{{R}_{4}} ) + \frac{( {B}_{1}^{a} - {B}_{2}^{a} )}{4 \sqrt{2}} ( \frac{Δ {R}_{6}}{{R}_{6}} - \frac{Δ {R}_{8}}{{R}_{8}} ) ] \\ {σ}_{12}^{′} = \frac{1}{{D}_{1}} [ \frac{( {B}_{2}^{b} - {B}_{3}^{b} )}{2} ( \frac{Δ {R}_{2}}{{R}_{2}} - \frac{Δ {R}_{4}}{{R}_{4}} ) - \frac{( {B}_{2}^{a} - {B}_{3}^{a} )}{2} ( \frac{Δ {R}_{6}}{{R}_{6}} - \frac{Δ {R}_{8}}{{R}_{8}} ) ] \\ T = \frac{1}{2 {D}_{2}} [ ( ( {B}_{1}^{c} + {B}_{2}^{c} ) {B}_{3}^{b} - ( {B}_{1}^{b} + {B}_{2}^{b} ) {B}_{3}^{c} ) ( \frac{Δ {R}_{1}}{{R}_{1}} + \frac{Δ {R}_{3}}{{R}_{3}} ) + ( ( {B}_{1}^{a} + {B}_{2}^{a} ) {B}_{3}^{c} - ( {B}_{1}^{c} + {B}_{2}^{c} ) {B}_{3}^{a} ) ( \frac{Δ {R}_{5}}{{R}_{5}} + \frac{Δ {R}_{7}}{{R}_{7}} ) + ( ( {B}_{1}^{b} + {B}_{2}^{b} ) {B}_{3}^{a} ) - ( {B}_{1}^{a} + {B}_{2}^{a} ) {B}_{3}^{b} ) ( \frac{Δ {R}_{9}}{{R}_{9}} + \frac{Δ {R}_{10}}{{R}_{10}} ) ] \\ Where , & ( 8 ) \\ {D}_{1} = {B}_{1}^{a} ( {B}_{2}^{b} - {B}_{3}^{b} ) + {B}_{2}^{a} ( {B}_{3}^{b} - {B}_{1}^{b} ) + {B}_{3}^{a} ( {B}_{1}^{b} - {B}_{2}^{b} ) \\ & ( 9 ) \\ {D}_{2} = {B}_{3}^{a} [ ( {B}_{1}^{b} + {B}_{2}^{b} ) {α}^{c} - ( {B}_{1}^{c} + {B}_{2}^{c} ) {α}^{b} ] + {B}_{3}^{b} [ ( {B}_{1}^{c} + {B}_{2}^{c} ) {α}^{a} - ( {B}_{1}^{a} + {B}_{2}^{a} ) {α}^{c} ] + {B}_{3}^{c} [ ( {B}_{1}^{a} + {B}_{2}^{a} ) {α}^{b} - ( {B}_{1}^{b} + {B}_{2}^{b} ) {α}^{a} ] & ( 10 )\end{matrix}$$

The nnn rosette can have n-type sensing elements for all three groups, but with different doping concentration designated as (1), (2) and (3) in Table 1. This selection of sensing elements can be attributed to the unique piezoresistive properties of n-Si compared to p-Si. In p-Si, the three crystallographic piezoresistive coefficients (π₁₁, π₁₂, and π₄₄) vary with the same factor upon variation of doping concentration and temperature [10, 15, 16]. This can hinder the possibility of developing an all p-type rosette. Therefore, in some embodiments, p-type sensing elements have to be combined with n-type sensing elements to solve (8).

In n-Si, the values of the on-axis piezoresistive coefficients π₁₁ and π₁₂ vary with the same factor in response to the change in doping concentration and temperature [15]. However, the shear piezoresistive coefficient π₄₄ in n-Si can behave in a different manner than the other two coefficients. Tufte et al. [10, 11] reported that upon change in impurity concentration, the absolute value of π₄₄ shows no change until an impurity concentration of around 10²⁰ cm⁻³, then it starts showing a logarithmic increase of its absolute value compared to the decreasing π₁₁ and π₁₂. Kanda et al. provided an analytical model to describe this behavior of π₄₄ with impurity concentration. The electron transfer theory can be used to describe correctly the behavior of π₁₁ and π₁₂ in n-Si. However, when used to describe the behavior of π₄₄ it suggested a zero value for the coefficient [18, 19]. Therefore, they proposed using the theory of effective mass change to describe the behavior of π₄₄ and it was found to satisfy the experimental results given by Tufte et al. [11]. Also, Nakamura et al. analytically modeled the n-Si piezoresistive behavior and discovered that π₄₄ hardly depends on concentration over the range from 1×10¹⁸ to 1×10²⁰ cm⁻³ [33]. Such behavior is paramount in the design of the single-polarity n-type sensing rosette because it helps create groups a, b, and c with independent B and α coefficients, thus providing independent equations (5)-(7).

### Temperature Effects

Piezoresistors can be sensitive to temperature variation, which changes the mobility and number of carriers. These temperature variations can affect the values of (1) the resistance of the sensing element by the temperature function [f(T)=α₁T+α₁T²+ . . . ], (2) the piezoresistive coefficients (π), and (3) the temperature coefficient of resistance, TCR (α). The reduction of these unwanted variations can impact on the calculated stresses is addressed in this section. The temperature function f(T) in piezoresistive sensors is usually eliminated by the addition of an unstressed resistor and use it to subtract the temperature effect from the stress sensitivity equations. However, this approach would be difficult to implement in applications that do not have an unstressed region in close proximity to the sensing rosette like in cases of embedded sensors. In some embodiments, two resistors of the same doping level and type can be adopted to subtract the temperature effects. This method is adopted in equations (5) and (6), therefore, the stresses extracted from (5) and (6) can be independent of temperature effect on resistance. On the other hand, f(T) can be included in (7) in order to be evaluated and compensate for its effect in the remaining stress equations, i.e. σ′₁₁, σ′₂₂, and σ′₃₃.

Experimental studies on the effect of temperature on π and doping concentrations were conducted by Tufte et al. [10] for a large range of concentrations and temperatures and compiled from the literature by Cho et al. [34]. It is noticeable that at high doping concentrations, the effect of temperature on π is decreased, which is verified analytically by Kanda et al. [15]. Similarly, at high doping levels the TCR value remains constant with temperature variations, thus giving a linear f(T) function. Cho et al. studied the effect of temperature on the TCR value on heavily doped n-type resistors from −180° C. to 130° C. They concluded that a first order TCR is adequate to model the f(T) function at high doping concentrations [35]. A similar conclusion is reached by Olszacki et al. for p-type silicon, where the quadratic terms in f(T) were found to approach zero at high doping levels [36].

Based on the previous behavior of π and TCR, the doping level of the proposed rosettes can be selected to be at high concentrations to minimize the effect of temperature on both π and TCR. In some embodiments, calibration of π and TCR can be carried out over the operating temperature range of the rosette, which can enhance the accuracy of the extracted stresses.

### Analytical Verification

In some embodiments, the analytical verification of the presented approach can be based on evaluating D₁ and D₂ at different doping concentrations for the three groups of sensing elements (a, b, and c) in order to study the behavior of D₁ and D₂ with concentration and their range of non-zero values. The analysis can be based on the analytical values of π for n- and p-Si given by Kanda [15], the experimental values of π₄₄ for n-Si given by Tufte et al. [11], and the experimental values of a for n- and p-Si given by Bullis et al. [25] for uniformly doped piezoresistors. The analysis can be carried out over a range of doping concentrations from 1×10¹⁸ to 1×10²⁰ cm⁻³ to avoid the constant behavior of the piezoresistive coefficients at low doping concentrations which will affect the linear independency of (5)-(7) and to minimize the effect of temperature on π and α.

D₁ and D₂ Coefficients

The evaluation of D₁ and D₂ at different concentrations for the npp and nnn rosettes are shown in FIG. 4 to FIG. 7, where Nₐ and N_{b} are the doping concentrations of groups a and b respectively. The doping concentration of group c for both rosettes is set at 5×10¹⁸ cm⁻³.

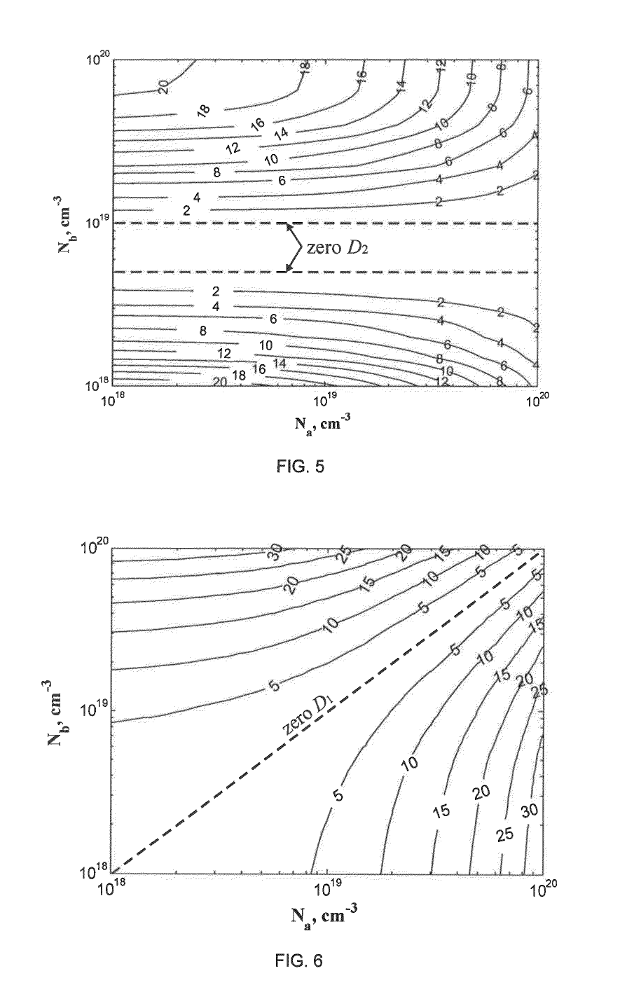

In the case of npp rosette, D₁ has a maximum at the low doping concentration (1×10¹⁸ cm⁻³) for both groups a and b of the analyzed range as shown in FIG. 4. On the other hand, D₂ is shown to have a maximum at (Nₐ, N_{b})=(1×10¹⁸ cm⁻³, 1×10¹⁸ cm³) and (1×10¹⁸ cm⁻³, 1×10²⁰ cm⁻³) as shown in FIG. 5. Regarding a zero determinant, |D₁| is always positive because groups a and b have independent π and α. Contrarily, D₂ reaches a zero value at two concentrations. The first is when group b has the same doping concentration as group c, i.e. 5×10¹³ cm⁻³ and the second when group b has the same TCR value of group c at 1×10¹⁹

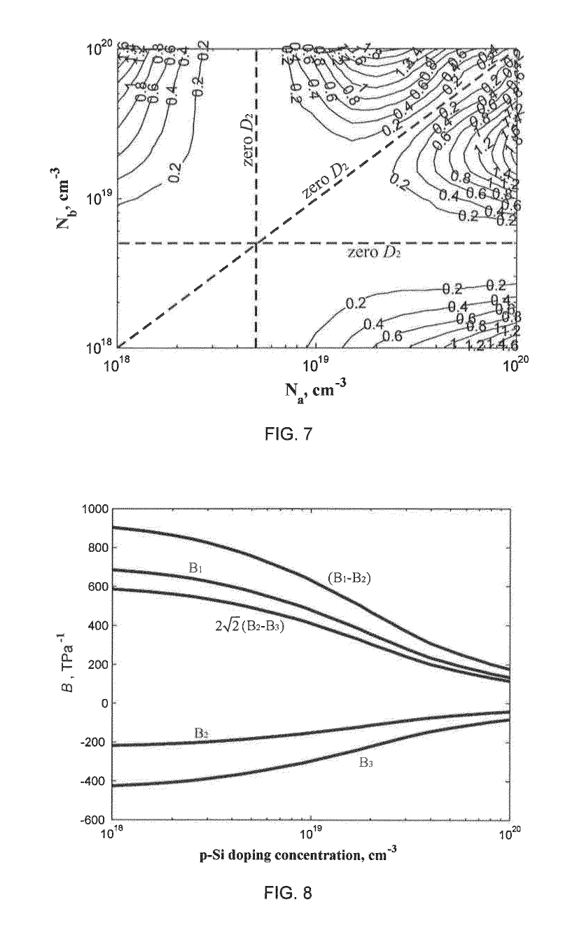

For nnn rosette, D₁ shown in FIG. 6 has a maximum at the boundaries of the range, i.e. at (Nₐ, N_{b})=(1×10¹⁸ cm⁻³, 1×10²⁰ cm³) and (1×10²⁰ cm⁻³, 1×10¹⁸ cm⁻³) and reaches zero when both groups a and b have the same doping concentration. The zero value occurs when groups a and b have the same coefficients, thus giving dependent equations (5)-(6). On the other hand, as shown in FIG. 7, D₂ has two peaks at (Nₐ, N_{b}) (1×10²⁰ cm³, 2×10¹⁹ cm⁻³) and (2×10¹⁹ cm⁻³, 1×10²⁰ cm⁻³) and reaches zero when: (1) both groups a and b have the same concentration and (2) any of groups a or b has the same concentration as group c (i.e. 5×10¹⁸ cm⁻³). These many zero valleys found in FIG. 7 requires more caution in the selection of the appropriate concentrations for groups a, b, and c. It is important to note that if a different concentration for group cis selected, the contour plots of D₂ can be different, but a non-zero solution can still be achieved.

It is clear that finding non-zero D₁ and D₂ is possible for both npp and nnn rosettes by selecting different doping concentration for each group. The relatively large range of non-zero D₁ and D₂ on the contour plots in FIG. 4 to FIG. 7 eases the process of doping by allowing larger tolerance on the concentration of the doped sensing elements. This is important in cases where the accuracy and reproducibility of the doping process is low as in the case of diffusion as compared to ion implantation,

### B and TCR Coefficients

The selection of the doping concentrations of groups a, b and c can be based on finding non-zero D₁ and D₂. However, another condition is still important to analyze, which is maximizing B and α. These coefficients can determine the sensitivity and output of the sensing elements for each of the seven components (six stress components and temperature) as given by (4). It is important to maximize the values of these coefficients to maximize the sensitivity and to avoid running into measurement errors during calibration. However, maximizing these coefficients means lowering the doping concentration, which maximizes the variation of the piezoresistive coefficients and TCR due to temperature changes. Therefore, in some embodiments, the doping concentration can be selected such that B and a can be maximized, while minimizing the effect of temperature on the coefficients.

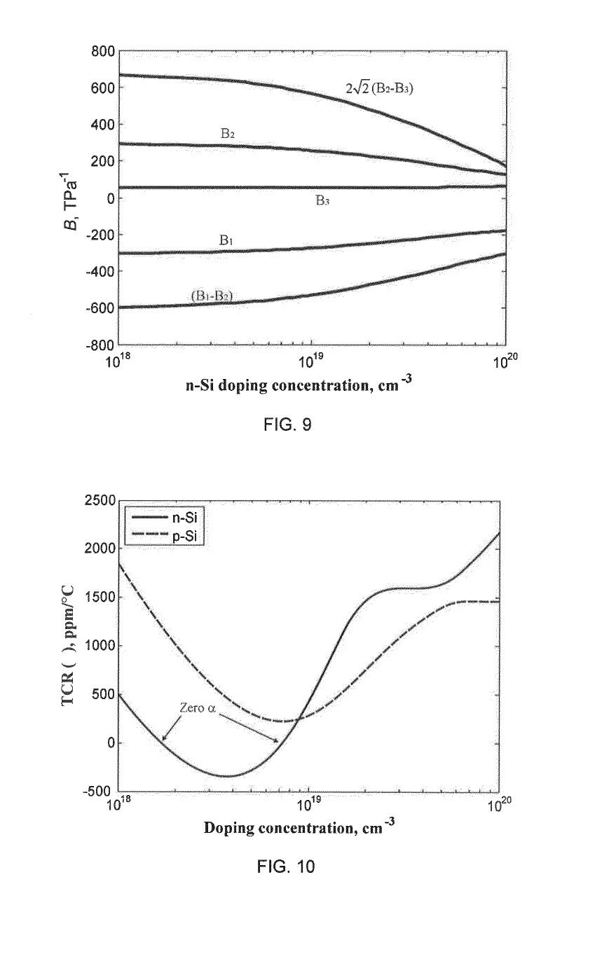

The B coefficients for p-Si, shown in FIG. 8, show a mutual decrease with the increase in doping concentration due to the common factor relating the piezoresistive coefficients with doping concentration. On the other hand, the B coefficients for n-Si in FIG. 9 decrease with doping concentration except for B₃, which shows an almost constant behavior with doping concentration. This constant trend of B₃ is due to its primary dependence on π₄₄, hick as noted earlier is independent of impurity concentration up to 1×10²⁰ cm⁻³. The TCR (α) curves for p- and n-Si with doping concentration is shown in FIG. 10 as extracted from the work of Bullis et al. [25], where α for n-Si is zero at around 1.5×10¹⁸ and 7×10¹⁸ cm⁻³. Therefore, it is important to avoid those values in order to avoid measurement errors during calibration.

The present analysis is based on assuming uniform doping concentration of the sensing elements. For actual sensor rosette fabricated using diffusion or ion implantation, the sensing elements can have non-uniform distribution of dopants across the thickness of the chip which follows either a Gaussian or complementary error function profile. This non-uniform doping of the sensing elements were not considered in the presented analysis due to the unavailability of enough experimental or analytical data for non-uniformly doped piezoresistors. However, according to Kerr et al., the surface dopant concentration could be used as an average effective concentration to model the piezoresistivity of diffused layers. [12].

### Experimental Verification

A preliminary experimental analysis to verify the feasibility of the proposed approach for the single polarity rosette (nnn) was carried out. The analysis verifies the feasibility of our approach of finding non-zero values of D₁ and D₂ for three groups of n-Si sensing elements at different concentrations. Test chips with the nnn sensing rosettes are microfabricated on (111) silicon wafers at the advanced MEMS/NEMS design laboratory and the NanoFab at the University of Alberta (U of A). A microphotograph of the fabricated ten-element nnn rosette is shown in FIG. 11 with the corresponding number for each resistor. Phosphorus diffusion with solid sources is used to create the three groups of serpentine-shaped resistors. The three concentrations were 2×10²⁰, 1.2×10²⁰ and 7×10¹⁹ cm⁻³ for groups a, b and c, respectively and as shown in FIG. 3 and as labelled in FIG. 11, which were characterized using secondary ion mass spectrometry (SIMS) in the ACSES lab at the U of A. This range of concentrations is slightly different than the previous analytical study due to the limitation with the used diffusion sources in reaching lower concentrations.

### Calibration

The evaluation of D₁ and D₂ for the fabricated rosette requires calibration of the B coefficients. The B₁ and B₂ coefficients are calibrated by applying uniaxial loading on the sensing elements oriented at 0° and 90° with respect to the 1-direction [ 1̅1̅0̅] (refer to FIG. 3). This gives the following normalized resistance change equations:

$$( \frac{Δ {R}_{0}}{{R}_{0}} ) = {B}_{1 ( eff )} {σ}_{11}^{′} \\ ( \frac{Δ {R}_{90}}{{R}_{90}} ) = {B}_{2 ( eff )} {σ}_{11}^{′} \qquad ( 11 )$$

where, B_{1(eff)} and B_{2(eff)} are effective values of the B coefficients which include the effect of the transverse sensitivity of the serpentine-shaped resistors. In order to eliminate this error and extract the fundamental values of the piezoresistive coefficients of silicon, the following correction relationship proposed by Cho et al. is used [37]:

$${B}_{1} = \frac{γ {B}_{1 ( eff )} + ( γ - 1 ) {B}_{2 ( eff )}}{2 γ - 1} \\ {B}_{1} = \frac{γ {B}_{2 ( eff )} + ( γ - 1 ) {B}_{1 ( eff )}}{2 γ - 1} \qquad ( 12 )$$

where γ is the ratio of the axial section to the sum of axial and transverse sections of the resistor, as shown in FIG. 11, such that γ=Nₐₓ/(Nₐₓ+Nₜᵣₐₙₛ) 1% and Nₐₓ and Nₜᵣₐₙₛ are the number of squares in the axial and transverse sections of the resistor.

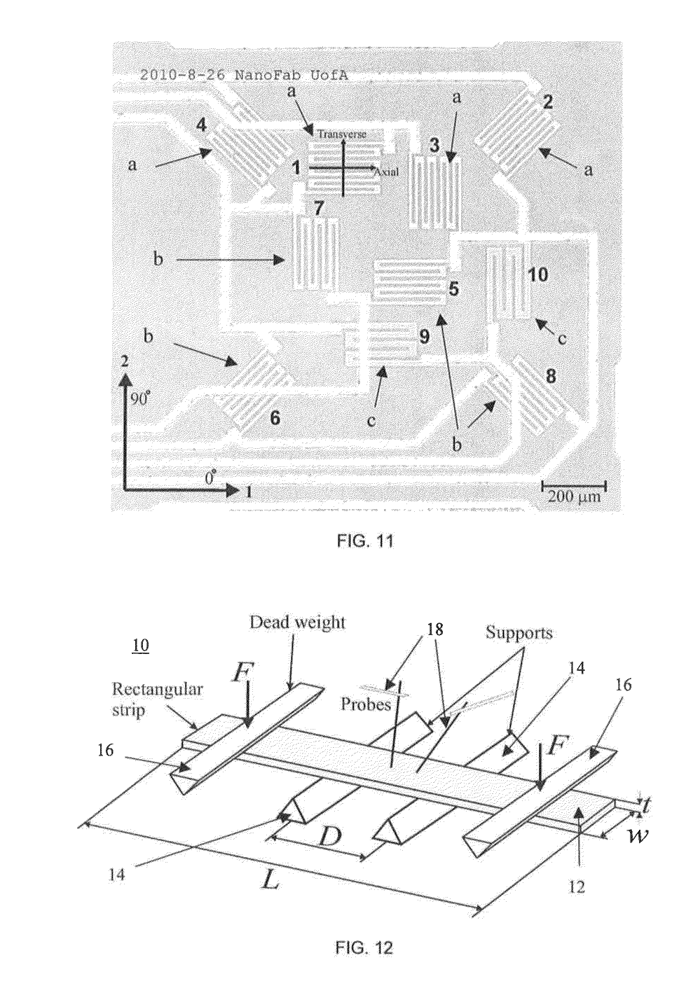

A four-point bending (4PB) fixture 10 was used to generate a uniaxial stress on a rectangular strip or beam 12 cut from the fabricated wafer as shown in FIG. 12, which contains a row of test chips. The four point loading develops a state of uniform bending stress between supports 14 at the middle section of the beam, which develops a state of uniaxial stress with a maximum value at the upper and lower surfaces of beam 12 given by [38]:

$${σ}_{11}^{′} = \frac{3 F ( L - D )}{{wt}^{2}} \qquad ( 13 )$$

where, F=applied force, L=distance between the two dead weights 16, D=distance between the middle supports 14, width of rectangular strip or beam 12, and t=thickness of rectangular strip 12. This equation is accurate if beam 12 is not significantly deformed due to the applied load, F, and the dimensions w and t are small compared to L and D.

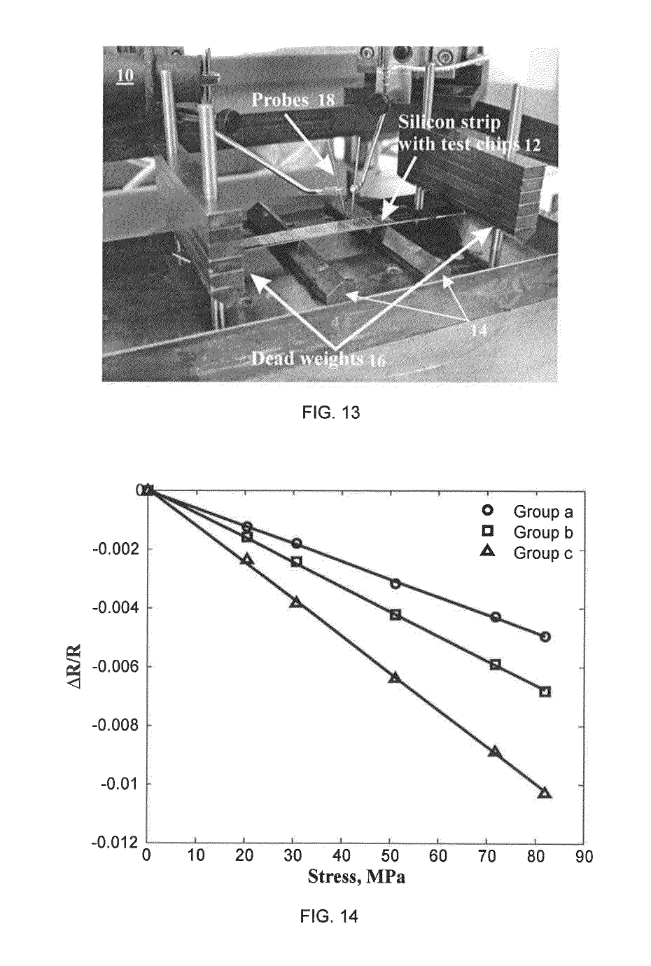

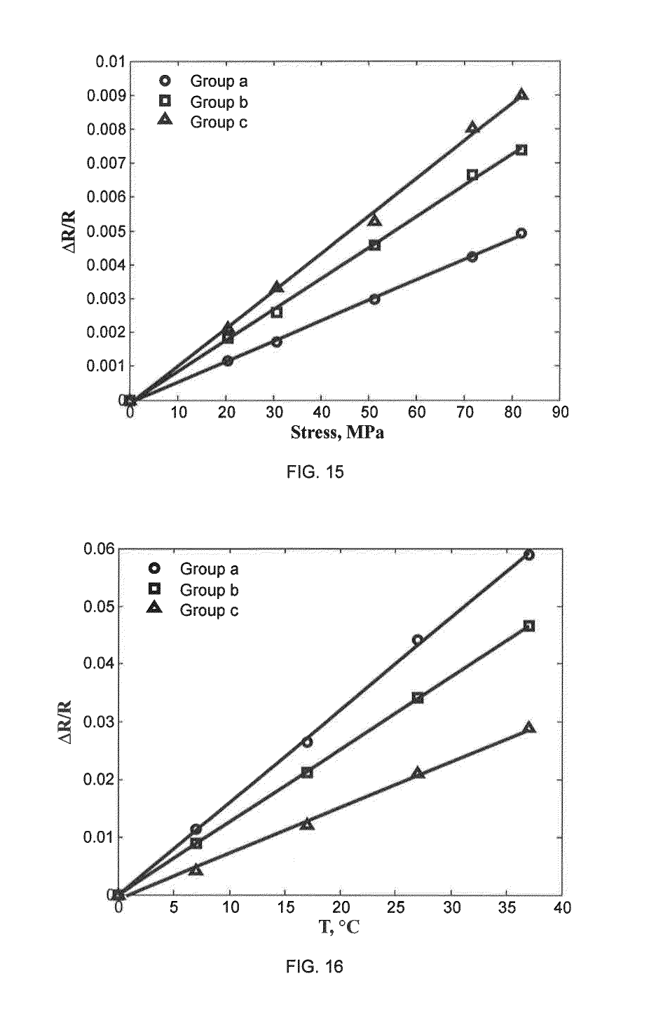

The applied σ′₁₁ stress generated between the two middle supports ranged from 0 to 82 MPa; and the measurement of the piezoresistors under loading is done using probes 18, as shown in FIGS. 12 and 13. Sample stress sensitivity data from the 4PB measurements for the R₀ and R₉₀ resistors are shown in FIG. 14 and FIG. 15, respectively.

The remaining piezoresistive coefficient B₃ requires an application of either a well-controlled out-of-plane shear stress (σ′₁₃ or σ′₂₃) or hydrostatic pressure. However, as a preliminary study, B₃ is evaluated based on the known relationship of the hydrostatic pressure coefficient (π_{P}) with B₁, B₂, and B₃, where π_{P}=−(B₁+B₂+B₃) as noted by Suhling of at [5]. Experimental values for π_{P} in n-Si is given by Tufte et al. over a concentration range from 1×10¹⁵ to 2×10²′ cm⁻³ and presented in Table 2 for each group of our resistors [11]. Once B₃ is evaluated, the fundamental piezoresistive coefficients are calculated from (3).

The temperature coefficient of resistance (α) is calibrated by using a hot plate to measure the change in resistance with temperature increase. The temperature is varied from 23° C. to 60° C. Sample temperature sensitivity measurements are shown in FIG. 16, where T represents the temperature change from 23° C. The measured values of B_{1(eff)}, B_{2(eff)}, and α as well as the calculated values of B and π for the three groups are shown in Table 2 along with their corresponding D₁ and D₂ values. These values are averaged over 10 specimens with their standard deviations noted between parentheses in the table.

The temperature coefficient of resistance (α) is calibrated by using a hot plate to measure the change in resistance with temperature increase. The temperature is varied from 23° C. to 60° C. Sample temperature sensitivity measurements are shown in FIG. 16, where T represents the temperature change from 23° C. The measured values of B_{1(eff)}, B_{2(eff)}, and α as well as the calculated values of B and π for the three groups are shown in Table 2 along with their corresponding D₁ and D₂ values. These values are averaged over 10 specimens with their standard deviations noted between parentheses in the table.

TABLE 2
EXPERIMENTAL VALUES FOR B, α AND D

| | Group | | | | | |
|---|---|---|---|---|---|---|
| | a | | b | | c | |
| N, cm⁻³ | 2 × 10²⁰ | | 1.2 × 10²⁰ | | 7 × 10¹⁹ | |
| πₚ, TPa⁻¹ [11] | 27 | | 26 | | 25 | |
| B_{1(eff)}, TPa⁻¹ | −72.0 | (13.5) | −76.5 | (10.4) | −116.3 | (13.6) |
| B_{2(eff)}, TPa⁻¹ | 64.7 | (11.1) | 69.0 | (10.4) | 108.1 | (4.5) |
| B₁, TPa⁻¹ | −75.2 | | −80.8 | | −124.5 | |
| B₂, TPa⁻¹ | 67.8 | | 73.3 | | 116.4 | |
| B₃, TPa⁻¹ | 34.4 | | 33.5 | | 33.1 | |
| π₁₁, TPa⁻¹ | −175.5 | | −200.1 | | −374.3 | |
| π₁₂, TPa⁻¹ | 101.2 | | 113.1 | | 199.7 | |
| π₄₄, TPa⁻¹ | −76.1 | | −74.5 | | −74.4 | |
| α, ppm/° C. | 1425.5 | (189) | 1208.6 | (162) | 1055.6 | (184) |

| | |
|---|---|
| \|D₁\|, TPa⁻² | 538.3 |
| \|D₂\|, ×10⁻³ | 3.1 |
| TPa⁻² ° C.⁻¹ | |

### D Coefficients

The results in Table 2 indicate that the present set of piezoresistors have non-zero D₁ and D₂ values, which proves the validity and feasibility of the proposed approach. An important observation from the experimental results is that although the concentration levels of groups a, b and c are dose, a solution is still possible for obtaining a non-zero D₁ and D₂. A larger difference between the concentrations of the three groups is expected to provide higher D values as indicated by the analytical study and illustrated in FIG. 6 and FIG. 7.

### Fundamental Piezoresistive Coefficients

A decreasing trend of the fundamental piezoresistive coefficients |π₁₁| and |π₁₂| is shown in Table 2 to develop in the range from group c (low concentration) to group a (higher concentration) with no major change in π₄₄. This aligns with the previous experimental results reported by Tufte et al. [11] and the analytical calculations by Kanda et al. [18, 19] and Nakamura et al. [33]. Consequently, the B coefficients presented in Table 2 demonstrate similar trends to those presented in FIG. 9, where B₁ and B₂ show a monotonic decrease from group c to group a, while B₃ shows almost no change. This behavior of π and B coefficients confirms the fundamental concept upon which the presented approach for npp and nnn rosettes is based, i.e. the independence of π₄₄ with impurity concentration. Thus, these results prove the feasibility to develop the nnn (single-polarity) and npp (dual-polarity) rosettes.

### TCR (α)

The values of TCR in Table 2 is seen to increase from 1055.6 ppm/° C. at low concentration to 1425.5 ppm/° C. at higher concentration. This trend agrees with the experimental results of Bullis et al. shown in FIG. 10 [25] and the analytical models of Norton et al. [26]. Moreover, the good linear fit of the TCR-resistance data proves that the assumption of neglecting the second order TCR is valid over the studied doping concentration and temperature ranges.

In some embodiments, a new approach is provided for developing a piezoresistive three-dimensional stress sensing rosette that can extract the six temperature-compensated stress components using either dual- or single-polarity sensing elements. In some embodiments, temperature-compensated stress components can be extracted by generating a new set of independent equations. In some embodiments, a technique is provided that can comprise three groups of sensing elements with independent piezoresistive coefficients (π) and temperature coefficient of resistance (TCR) and can further use the unique behavior of π₄₄ in n-Si to construct dual- and single-polarity rosettes.

In some embodiments, the piezoresistive resistor sensor as described herein can be used as micro stress sensors for a variety of applications. In some embodiments, the sensor can be used to monitor the thermal and mechanical loads affecting an electronic circuit or chip during its packaging or operation. The sensor can act as a device for monitoring the structural characteristics of an electronic chip. In other embodiments, the sensor can also be used to monitor the operation of the chip under thermal and mechanical loading to provide data that can be used to design electronic circuits and chips that can withstand greater thermal and mechanical loads and stresses.

In other embodiments, the sensor can be incorporated into a strain or stress gauge or device for use in monitoring the strain or stress on or within a structural member. For the purposes of this specification, the strain gauge or device can be placed on a surface of the structural member or embedded within the structural member as obvious to those skilled in the art. In addition, a structural member can include a structural element of a machine, a vehicle, a building structure, an electronic device, a bio-implant, a neural or spinal cord probe or electrode, an electro-mechanical apparatus and any other structural element of an object as well known to those skilled in the art.

Although a few embodiments have been shown and described, it will be appreciated by those skilled in the art that various changes and modifications might be made without departing from the scope of the invention. The terms and expressions used in the preceding specification have been used herein as terms of description and not of limitation, and there is no intention in the use of such terms and expressions of excluding equivalents of the features shown and described or portions thereof, it being recognized that the invention is defined and limited only by the claims that follow.

### REFERENCES

The following documents are hereby incorporated by reference into this application in their entirety,
[1] D. Benfield, E. Lou, and W. Moussa, “Development of a MEMS-based sensor array to characterise in situ loads during scoliosis correction surgery,” Computer Methods in Biomechanics and Biomedical Engineering, vol. 11, no. 4, pp. 335-350, August, 2008.
[2] F. Goericke, J. C. Lee, and W. P. King, “Microcantilever hotplates with temperature-compensated piezoresistive strain sensors,” Sensors and Actuators a-Physical, vol, 143, no. 2, pp. 181-190, May 16, 2008.
[3] A. A. S. Mohammed, W. A. Moussa, and E. Lou, “Optimization of geometric characteristics to improve sensing performance of MEMS piezoresistive strain sensors,” Journal of Micromechanics and Microengineering, vol. 20, no, 1, pp., January, 2010.
[4] Schwizer, M. Mayer, O. Brand et al., “Force sensors for microelectronic packaging applications,” Microtechnology and MEMS, Springer, 2005, pp. viii, 178 p.
[5] C. Suhling, and R. C. Jaeger, “Silicon piezoresistive stress sensors and their application in electronic packaging,” Sensors Journal, IEEE, vol. 1, no. 1, pp. 14-30, 2001.
[6] F. Alfaro, L. Weiss, P. Campbell et al., “Design of a multi-axis implantable MEMS sensor for intraosseous bone stress monitoring,” Journal of Micromechanics and Microengineering, vol. 19, no. 8, pp., August, 2009.
[7] C. Hautamaki, S. Zurn, S. C. Mantell et al., “Experimental evaluation of MEMS strain sensors embedded in composites,” Microelectromechanical Systems, Journal of, vol. 8, no. 3, pp. 272-279, 1999.
[8] C. S. Smith, “Piezoresistance Effect in Germanium and Silicon,” Physical Review, vol. 94, no. 1, pp. 42-49, 1954.
[9] W. Paul, and G. L. Pearson, “Pressure Dependence of the Resistivity of Silicon,” Physical Review, vol. 98, no, 6, pp. 1755-1757, 1955.
[10] O. N. Tufte, and E. L. Stelzer, “Piezoresistive Properties of Silicon Diffused Layer,” Journal of Applied Physics, vol. 34, no. 2, pp. 313-318, 1963.
[11] O. N. Tufte, and E. L. Stelzer, “Piezoresistive Properties of Heavily Doped n-Type Silicon,” Physical Review, vol. 133, no. 6A, pp. A1705, 1964.
[12] D. R. Kerr, and A. G. Milnes, “Piezoresistance of Diffused Layers in Cubic Semiconductors,” Journal of Applied Physics, vol. 34, no. 4, pp. 727-&, 1963.
[13] F. J. Morin, T. H. Geballe, and C. Herring, “Temperature Dependence of the Piezoresistance of High-Purity Silicon and Germanium,” Physical Review, vol. 105, no. 2, pp. 525-539, 1957.
[14] J. Richter, O. Hansen, A. N. Larsen et al., “Piezoresistance of silicon and strained Si0.9Ge0.1,” Sensors and Actuators a-Physical, vol. 123-24, pp. 388-396, Sep. 23, 2005,
[15] Y. Kanda, “A graphical representation of the piezoresistance coefficients in silicon,” Electron Devices, IEEE Transactions on, vol. 29, no, 1, pp. 64-70, 1982.
[16] Y. Kanda, “Piezoresistance effect of silicon,” Sensors and Actuators, A: Physical, vol, 28, no. 2, pp. 83-91, 1991.
[17] Y. Kanda, and K. Matsuda, “Piezoresistance effect in p-type silicon,” Physics of Semiconductors, Pts A and B, vol. 772, pp. 79-80 1594, 2005.
[18] Y. Kanda, and K. Matsuda, “Piezoresistance Effect of n-type Silicon; Temperature and Concentration Dependencies, Stress Dependent Effective Masses,” AIP Conference Proceedings, vol. 893, no. 1, pp. 173-174, 2007.
[19] Y. Kanda, and K. Suzuki, “Origin of the shear piezoresistance coefficient pi 44 of n-type silicon,” Physical Review B, vol. 43, no. 8, pp. 6754, 1991.
[20] K. Matsuda, Y. Kanda, and K. Suzuki, “2nd-Order Piezoresistance Coefficients of N-Type Silicon,” Japanese Journal of Applied Physics Part 2-Letters, vol. 28, no, 10, pp. L1676-L1677, October, 1989.
[21] K. Matsuda, Y. Kanda, K. Yamamura et al., “2nd-Order Piezoresistance Coefficients of P-Type Silicon,” Japanese Journal of Applied Physics Part 2-Letters& Express Letters, vol, 29, no, 11, pp. L1941-L1942, November, 1990.
[22] S. I. Kozlovskiy, and I. I. Boiko, “First-order piezoresistance coefficients in silicon crystals,” Sensors and Actuators a-Physical, vol. 118, no. 1, pp. 33-43, Jan. 31, 2005.
[23] T. Toriyama, and S. Sugiyama, “Analysis of piezoresistance in p-type silicon for mechanical sensors,” Journal of Microelectromechanical Systems, vol. 11, no. 5, pp. 598-604, October, 2002.
[24] Richter, J. Pedersen, M. Brandbyge et al., “Piezoresistance in p-type silicon revisited,” Journal of Applied Physics, vol. 104, no. 2, pp., Jul. 15, 2008.
[25] W. M. Bullis, F. H. Brewer, C. D. Kolstad et al., “Temperature coefficient of resistivity of silicon and germanium near room temperature,” Solid-State Electronics, vol. 11, no. 7, pp. 639-646, 1968.
[26] P. Norton, and J. Brandt, “Temperature-Coefficient of Resistance for P-Type and N-Type Silicon,” Solid-State Electronics, vol, 21, no, 7, pp. 969-974, 1978.
[27] A. Boukabache, and R. Pons, “Doping effects on thermal behaviour of silicon resistor,” Electronics Letters, vol. 38, no. 7, pp. 342-343, 2002.
[28] H. Miura, A. Nishimura, S. Kawai et al., “Structural Effect of Ic Plastic Package on Residual-Stress in Silicon Chips,” 40th Electronic Components and Technology Conference, Vols 1 and 2, pp. 316-321, 1125, 1990.
[29] D. A. Bittle, J. C. Suhling, R. E. Beaty et al., “Piezoresistive stress sensors for structural analysis of electronic packages,” Journal of Electronic Packaging, vol. 113, no. 3, pp. 203-215, 1991.
[30] B. J. Lwo, J. S. Su, and H. Chung, “In Situ Chip Stress Extractions for LFBGA Packages Through Piezoresistive Sensors,” Journal of Electronic Packaging, vol. 131, no. 3, pp., September, 2009.
[31] A. Mian, J. C. Suhling, and R. C. Jaeger, “The van der Pauw stress sensor,” IEEE Sensors Journal, vol, 6, no. 2, pp. 340-356, April, 2006.
[32] R. A. Cordes, J. C. Suhling, Y. L. Kang et al., “Optimal temperature compensated piezoresistive stress sensor rosettes,” American Society of Mechanical Engineers, EEP. pp. 109-116.
[33] K. Nakamura, Y. Isono, T. Toriyama et al., “Simulation of piezoresistivity in n-type single-crystal silicon on the basis of the first-principles band structure,” Physical Review B, vol. 80, no. 4, pp., July, 2009.
[34] C. H. Cho, R. C. Jaeger, and J. C. Suhling, “Characterization of the temperature dependence of the piezoresistive coefficients of silicon from −150 degrees C. to +125 degrees C.,” IEEE Sensors Journal, vol. 8, no. 7-8, pp. 1455-1468, July-August, 2008.
[35] C. H. Cho, R. C. Jaeger, J. C. Suhling et al., “Characterization of the temperature dependence of the pressure coefficients of n- and p-type silicon using hydrostatic testing,” IEEE Sensors Journal, vol. 8, no, 3-4, pp. 392-400, March-April, 2008.
[36] M. Olszacki, C. Maj, M. Al Bahri et al., “Experimental verification of temperature coefficients of resistance for uniformly doped P-type resistors in SOI,” Journal of Micromechanics and Microengineering, vol. 20, no. 6, pp., June, 2010.
[37] C. H. Cho, R. C. Jaeger, and J. C. Suhling, “The Effect of the Transverse Sensitivity on Measurement of the Piezoresistive Coefficients of Silicon,” Japanese Journal of Applied Physics, vol. 47, no. 5, pp. 3647-3656, May, 2008.
[38] R. E. Beaty, R. C. Jaeger, J. C. Suhling et al., “Evaluation of Piezoresistive Coefficient Variation in Silicon Stress Sensors Using a 4-Point Bending Test Fixture,”Ieee Transactions on Components Hybrids and Manufacturing Technology, vol. 15, no. 5, pp. 904-914, October, 1992.

1. A stress sensor, comprising:
a) a semiconductor substrate;
b) a plurality of piezoresistive resistors disposed on the substrate, the resistors spaced-apart on the substrate in a rosette formation, the resistors operatively connected together to form a circuit network wherein the resistance of each resistor can be measured; and
c) the plurality of piezoresistive resistors comprising a first group of resistors, a second group of resistors, and a third group of resistors, wherein the three groups of resistors are configured to measure six temperature-compensated stress components in the substrate when the sensor is under stress or strain.

2. The sensor as set forth in claim 1, wherein the resistors comprise doped silicon.

3. The sensor as set forth in claim 2, wherein the resistors comprise n-type doped silicon.

4. The sensor as set forth in claim 2, wherein the first group of resistors comprises n-type doped silicon, and the second and third groups of resistors comprise p-type doped silicon.

5. The sensor as set forth in claim 2, wherein the doping concentration of the resistors in each group is different from each other.

6. The sensor as set forth in claim 1, wherein the first group comprises four resistors, the second group comprises four resistors, and the third group comprises two resistors.

7. A strain gauge comprising a sensor, the sensor comprising:
a) a semiconductor substrate;
b) a plurality of piezoresistive resistors disposed on the substrate, the resistors spaced-apart on the substrate in a rosette formation, the resistors operatively connected together to form a circuit network wherein the resistance of each resistor can be measured; and
c) the plurality of piezoresistive resistors comprising a first group of resistors, a second group of resistors, and a third group of resistors, wherein the three groups of resistors are configured to measure six temperature-compensated stress components in the substrate when the sensor is under stress or strain.

8. The strain gauge as set forth in claim 7, wherein the resistors comprise doped silicon.

9. The strain gauge as set forth in claim 8, wherein the resistors comprise n-type doped silicon.

10. The strain gauge as set forth in claim 8, wherein the first group of resistors comprises n-type doped silicon, and the second and third groups of resistors comprise p-type doped silicon.

11. The strain gauge as set forth in claim 8, wherein the doping concentration of the resistors in each group is different from each other.

12. The strain gauge as set forth in claim 7, wherein the first group comprises four resistors, the second group comprises four resistors, and the third group comprises two resistors.

13. A method for measuring the strain on an electronic chip comprising a semiconductor substrate, the method comprising:
a) fabricating the electronic chip with a plurality of piezoresistive resistors disposed on the substrate, the resistors spaced-apart on the substrate in a rosette formation, the resistors operatively connected together to form a circuit network wherein the resistance of each resistor can be measured, the plurality of piezoresistive resistors comprising a first group of resistors, a second group of resistors, and a third group of resistors, wherein the three groups of resistors are configured to measure six temperature-compensated stress components in the substrate when the sensor is under stress or strain;
b) subjecting the electronic chip to a mechanical or thermal load;
c) measuring the resistance of the resistors; and
d) determining the six temperature-compensated stress components of the substrate from the resistance measurements.

14. The method as set forth in claim 13, wherein the resistors comprise doped silicon.

15. The method as set forth in claim 14, wherein the resistors comprise n-type doped silicon.

16. The method as set forth in claim 14, wherein the first group of resistors comprises n-type doped silicon, and the second and third groups of resistors comprise p-type doped silicon.

17-18. (canceled)

19. A method for measuring strain or stress on a structural member, the method comprising:
a) placing a strain gauge on or within the structural member, the strain gauge comprising a sensor, the sensor further comprising:
i) a semiconductor substrate,
ii) a plurality of piezoresistive resistors disposed on the substrate, the resistors spaced-apart on the substrate in a rosette formation, the resistors operatively connected together to form a circuit network wherein the resistance of each resistor can be measured, and
iii) the plurality of piezoresistive resistors comprising a first group of resistors, a second group of resistors, and a third group of resistors, wherein the three groups of resistors are configured to measure six temperature-compensated stress components in the substrate when the sensor is under stress or strain;
b) subjecting the structural member to a mechanical or thermal load;
c) measuring the resistance of the resistors; and
d) determining the six temperature-compensated stress components of the substrate from the resistance measurements.

20. The method as set forth in claim 19, wherein the resistors comprise doped silicon.

21. The method as set forth in claim 20, wherein the resistors comprise n-type doped silicon.

22. The method as set forth in claim 20, wherein the first group of resistors comprises n-type doped silicon, and the second and third groups of resistors comprise p-type doped silicon.

23-24. (canceled)
